(19) United States
(12) Patent Application Publication
(10) Pub. No.: US 2023/0115690 A1
(43) Pub. Date: Apr. 13, 2023

(54) OPTICAL ASSEMBLY THAT INCLUDES AN OPTICAL ELEMENT CONNECTED TO A VERTICAL CAVITY SURFACE EMITTING LASER DEVICE VIA TWO OR MORE ATTACHMENT STRUCTURES

(71) Applicant: Lumentum Operations LLC, San Jose, CA (US)

(72) Inventors: Wei SHI, San Jose, CA (US); Kevin WANG, Fremont, CA (US); Hao HUANG, San Jose, CA (US); John Michael MILLER, Ottawa (CA); Siu Kwan CHEUNG, San Jose, CA (US); Lijun ZHU, Pleasanton, CA (US)

(21) Appl. No.: 17/644,679

(22) Filed: Dec. 16, 2021

Related U.S. Application Data
(60) Provisional application No. 63/262,288, filed on Oct. 8, 2021.

(51) Int. Cl. H01S 5/42; H01S 5/042; H01S 5/183; H01S 5/026

(52) U.S. Cl. CPC H01S 5/423; H01S 5/04256; H01S 5/18388; H01S 5/026

(57) ABSTRACT

An optical assembly includes an integrated circuit (IC) driver chip; an optical subassembly disposed on the IC driver chip that includes: a vertical cavity surface emitting laser (VCSEL) device, an optical element disposed above a top surface of the VCSEL device, and two or more attachment structures disposed between the VCSEL device and the optical element; and two or more additional attachment structures disposed between the IC driver chip and the optical subassembly. The VCSEL device includes: a cathode contact disposed on the top surface of the VCSEL device, and an anode contact disposed on the top surface of the VCSEL device. The optical element includes two or more conductive traces on a bottom surface of the optical element. The two or more attachment structures are disposed between the two or more conductive traces of the optical element, and the cathode contact and the anode contact of the VCSEL device.

### RELATED APPLICATION

This application claims priority to U.S. Provisional Patent Application No. 63/262,288, for “MINIATURE PACKAGE DESIGN WITH INTEGRATED INDIUM TIN OXIDE CONNECTION AND ELECTROMAGNETIC INTERFERENCE SHIELDING,” filed on Oct. 8, 2021, the content of which is incorporated by reference herein in its entirety.

### TECHNICAL FIELD

The present disclosure relates generally to an optical assembly and to an optical assembly with an optical subassembly comprising a vertical cavity surface emitting laser (VCSEL) device and an optical component.

### BACKGROUND

Time-of-flight (ToF) systems, such as three-dimensional (3D) sensing systems, light detection and ranging (LIDAR) systems, and/or the like, emit optical pulses into a field of view, detect reflected optical pulses, and determine distances to objects in the field of view by measuring delays and/or differences between the emitted optical pulses and the reflected optical pulses.

### SUMMARY

In some implementations, an optical subassembly includes a vertical cavity surface emitting laser (VCSEL) device; an optical element disposed above a top surface of the VCSEL device; and two or more attachment structures disposed between the VCSEL device and the optical element, wherein: the VCSEL device includes: a cathode contact disposed on the top surface of the VCSEL device, and an anode contact disposed on the top surface of the VCSEL device; the optical element includes two or more conductive traces on a bottom surface of the optical element; and the two or more attachment structures are disposed between the two or more conductive traces of the optical element, and the cathode contact and the anode contact of the VCSEL device.

In some implementations, an optical assembly includes an integrated circuit (IC) driver chip; an optical subassembly disposed on the IC driver chip that includes: a VCSEL device, an optical element disposed above a top surface of the VCSEL device, and two or more attachment structures disposed between the VCSEL device and the optical element; and two or more additional attachment structures disposed between the IC driver chip and the optical subassembly, wherein: the VCSEL device includes: a cathode contact disposed on the top surface of the VCSEL device, and an anode contact disposed on the top surface of the VCSEL device; the optical element includes two or more conductive traces on a bottom surface of the optical element; and the two or more attachment structures are disposed between the two or more conductive traces of the optical element, and the cathode contact and the anode contact of the VCSEL device.

In some implementations, an optical assembly includes a substrate; an IC driver chip disposed on the substrate; an optical subassembly disposed on the IC driver chip that includes: a VCSEL device, an optical element disposed above a top surface of the VCSEL device, and two or more attachment structures disposed between the VCSEL device and the optical element; and two or more additional attachment structures disposed between the IC driver chip and the optical subassembly, wherein: the VCSEL device includes: a cathode contact disposed on the top surface of the VCSEL device, and an anode contact disposed on the top surface of the VCSEL device; the optical element includes two or more conductive traces on a bottom surface of the optical element; and the two or more attachment structures are disposed between the two or more conductive traces of the optical element, and the cathode contact and the anode contact of the VCSEL device.

### BRIEF DESCRIPTION OF THE DRAWINGS

FIGS. 1A-1B are diagrams of an example optical assembly described herein.

FIG. 2 is a diagram of an example optical assembly described herein.

FIG. 3 is a diagram of an example optical assembly described herein.

### DETAILED DESCRIPTION

The following detailed description of example implementations refers to the accompanying drawings. The same reference numbers in different drawings may identify the same or similar elements.

A projector module can be used for a three-dimensional (3D) sensing application, such as a time-of-flight (TOF) application. The projector module may include an emitter array (e.g., a VCSEL array), a lens, a diffractive optical element (DOE), and an IC driver chip. In operation, the IC driver chip provides an electrical signal to cause the emitter array to emit light (e.g., infrared (IR) light), which is collimated by the lens, and beams of collimated light (each corresponding to a respective emitter) are directed to the DOE. The DOE distributes the collimated beams of light to create a dot projection (e.g., a projection of the collimated beams) on a subject. More specifically, the DOE diffracts a given beam of light such that diffracted orders of the given beam are transmitted by the DOE at different angles. The projector module may include one or more additional elements (e.g., one or more sensors, processors, and/or the like) to sense the dot projection and make one or more measurements concerning the subject based on the dot projection.

Typically, the emitter array and the IC driver chip are disposed on a surface of a substrate (e.g., a flame retardant (FR) substrate, such as an FR4 substrate, or a high temperature co-fired ceramic (HTCC) substrate) of the projector module (e.g., a top surface of the substrate). However, the IC driver chip occupies a large region of the surface of the substrate, which increases a size of the substrate and therefore increases a size (e.g., an XY footprint) of the projector module. Moreover, a projector module often includes a photodiode (PD) that can detect an in-field failure of the lens or another optical element (e.g., when the lens is broken or has fallen off a housing of the projector module). When the PD detects an in-field failure, the IC driver chip shuts down the emitter array of the projector module (e.g., to prevent further emission of light by the emitter array for eye safety compliance). However, inclusion of the PD in the projector module further increases the size (e.g., the XY footprint) of the projector module. Additionally, the inclusion of both a lens and a DOE in the projector model increases a thickness (e.g., a Z height) of the projector module. Thus, the size and height of a projector model prevents the projector module from being included in some user devices, such as smart phones.

Further, the DOE includes a glass substrate that includes a conductive circuit formed as a layer on a surface of the substrate. The circuit is configured to detect a change in resistance associated with damage to the glass substrate (e.g., when the glass substrate is broken, broken off from the DOE, and/or the like). The circuit typically comprises Indium Tin Oxide (ITO) and is bonded to a housing (e.g., a plastic housing) of the projector module via two ITO terminal pads that are connected to a pair of laser direct structuring (LDS) traces that are formed on a surface of the housing. The LDS traces are connected to the IC driver chip of the projector module. When the circuit detects a change in resistance, the IC driver chip will shut down the emitter array (e.g., to prevent further emission of light by the emitter array for eye safety compliance). Inclusion of the conductive circuit, ITO terminal pads, and LDS traces increases a complexity of designing and assembling the projector module.

In some cases, the projector module includes electromagnetic interference (EMI) shielding (e.g., a metal shield that is soldered on top of the projector module). The EMI shielding is often larger than the projector module and not integrated into a package of the projector module, and therefore increases a size and/or thickness of the projector module.

Moreover, in a projector module, the emitter array includes a cathode on a bottom surface of the emitter array, which is disposed on the surface of the substrate. The cathode functions as an electrical current path and a heat dissipation path, and therefore requires multiple layers of dielectric material to be included in the substrate. This impedes a thermal conductivity of the substrate. Consequently, the projector module suffers from a high thermal resistance that decreases an optical power output of the projector module (e.g., due to a high emitter junction temperature associated with the emitter array of the projector module).

Some implementations described herein provide an optical assembly for an electro-optical device, such as a ToF device. The optical assembly includes a substrate, an integrated circuit (IC) driver chip disposed on the substrate, and an optical subassembly disposed on the IC driver chip (e.g., in a vertical stack). The optical subassembly includes a vertical cavity surface emitting laser (VCSEL) device, an optical element disposed on a top surface of the VCSEL device, and two or more attachment structures disposed between the VCSEL device and the optical element. Accordingly, by disposing the optical subassembly (that includes the VCSEL device) over the IC driver chip (e.g., instead of positioning the VCSEL device and the IC driver chip next to each other), the optical assembly has a reduced size as compared to that of the projector module described above and, thus, a size (e.g., an XY footprint) of the electro-optical device is reduced as compared to a size of the projector module described above. This enables the electro-optical device to be included in some user devices, such as smart phones.

The VCSEL device includes a plurality of emitters and a microlens component. The microlens component is disposed over the plurality of emitters and on a top surface of the VCSEL device. The microlens component collimates light emitted by the VCSEL device as the VCSEL device emits light, and therefore a collimating lens and a PD that is configured to detect a failure associated with a collimating lens do not need to be included in the optical assembly. In this way, a size of the optical subassembly is additionally reduced and, thus, a size (e.g., an XY footprint) of the electro-optical device is additionally reduced as compared to a size of the projector module described above. Foregoing inclusion of the collimating lens also reduces a thickness (e.g., a Z height) of the electro-optical device as compared to a thickness of the projector module described above. Additionally, because of these size and thickness reductions, an EMI shield may be directly disposed on the substrate of the optical assembly and/or use of a housing may be eliminated, which further reduces a size and thickness of the electro-optical device.

In some implementations, the VCSEL device includes a cathode contact and an anode contact that are disposed on a top surface of the VCSEL device. In this way, a bottom surface of the VCSEL device, which is electrically insulated, is directly disposed on the IC driver chip. Further, the IC driver chip is directly disposed on the substrate, which, in some implementations, includes a thermally conductive core. Accordingly, the IC driver chip, the substrate, and/or the thermally conductive core are configured to thermally conduct heat generated by the VCSEL device (e.g., when emitting light) away from the optical assembly. This reduces a number of dielectric layers through which heat generated by the VCSEL device has to pass in the optical assembly. Therefore, the electro-optical device has an improved thermal performance as compared to the projector module described above, which causes the electro-optical device to have an increased optical power output as compared to the optical power output of the projector module described above (e.g., due to a lower VCSEL junction temperature associated with the VCSEL device of the electro-optical device).

In some implementations, the optical element of the optical subassembly is a diffractive optical element (DOE) and/or a diffuser (e.g., comprising a glass material) and includes two or more conductive traces on a bottom surface of the optical element. In some implementations, the two or more attachment structures of the optical subassembly are disposed between the two or more conductive traces of the optical element and the cathode contact and the anode contact of the VCSEL device. For example, a first conductive trace and a first attachment structure may be associated with the cathode contact such that the first attachment structure is disposed between the first conductive trace and the cathode contact (e.g., to form a first electrical path associated with the cathode contact). As another example, a second conductive trace and a second attachment structure may be associated with the anode contact such that the second attachment structure is disposed between the second conductive trace and the anode contact (e.g., to form a second electrical path associated with the anode contact). Further, the optical assembly may include two or more additional attachment structures that are disposed between the two or more conductive traces of the optical element and a top surface of the IC driver chip. For example, a first additional attachment structure may be associated with the cathode contact such that the first additional attachment structure is disposed between the first conductive trace and a first region of the top surface of the IC driver chip (e.g., to further form the first electrical path, which electrically connects the cathode contact and the top surface of the IC driver chip). As another example, a second additional attachment structure may be associated with the anode contact such that the second additional attachment structure is disposed between the second conductive trace and a second region of the top surface of the IC driver chip (e.g., to further form the second electrical path, which electrically connects the anode contact and the top surface of the IC driver chip). Accordingly, sets of the two or more conductive traces, the two or more attachment structures, and the two or more additional attachment structures are electrically connected and are configured to transmit electrical signals (e.g., provided by the IC driver chip) to or from the VCSEL device (e.g., to cause the VCSEL device to emit an output beam).

Additionally, or alternatively, the two or more conductive traces are configured to prevent transmission of electricals signal to or from the VCSEL device when at least one of the optical element or at least one of the two or more conductive traces are damaged or broken. In this way, a conductive circuit, ITO terminal pads, and LDS traces do not need to be included in the optical assembly, which reduces a complexity of designing and assembling the optical assembly, as compared to that of the projector module described above.

In some implementations, the optical subassembly includes one or more sealing structures that form a seal between the optical element and the VCSEL device, thereby creating a hermetically sealed internal space of the optical subassembly (e.g., that is bounded by the VCSEL device, the optical element, the one or more attachment structures, and/or the one or more sealing structures). This prevents dust, debris, humidity, or other contaminants from damaging or interfering with the VCSEL device and/or the optical element, which improves a performance and/or durability of the optical assembly over an operating life of the optical assembly.

In some implementations, the optical element is directly connected to the VCSEL device (e.g., via the two or more attachment structures) during assembly of the optical assembly. Accordingly, this eliminates a need for a time consuming and expensive active alignment process (e.g., to align a VCSEL device and an optical element of the projector module described above) because the VCSEL device can be connected to the optical element with a particular amount of accuracy (e.g., within a tolerance of 5 microns in an XY direction).

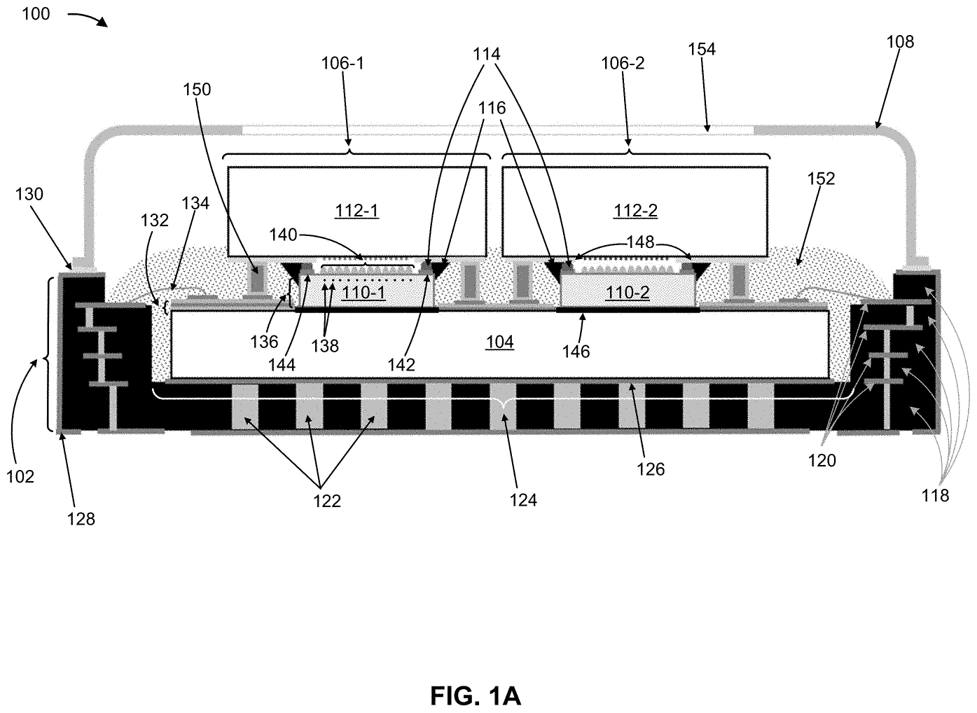

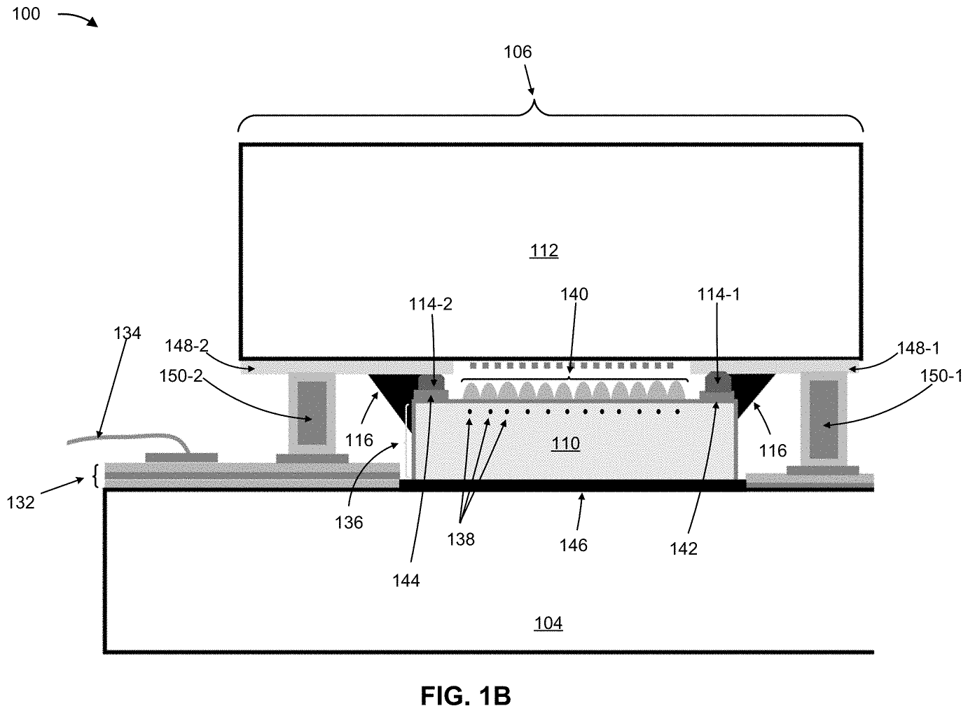

FIGS. 1A-1B are diagrams of an example optical assembly 100 for an electro-optical device, such as a ToF device. FIG. 1A illustrates a side cut-away view of the optical assembly 100. FIG. 1B illustrates a close-up view of a portion of the optical assembly 100. As shown in FIGS. 1A-1B, the optical assembly 100 may include a substrate 102, an integrated circuit (IC) driver chip 104, one or more optical subassemblies 106 (shown as optical subassemblies 106-1 and 106-2 in FIG. 1A), and/or an EMI shield 108. An optical subassembly 106 may include a VCSEL device 110, an optical element 112, two or more attachment structures 114 (shown as attachment structures 114-1 and 114-2 in FIG. 1B), and/or one or more sealing structures 116.

The substrate 102 may be an open-cavity ceramic substrate, such as an open-cavity high temperature co-fired ceramic (HTCC) substrate, an open-cavity low temperature co-fired ceramic (LTCC) substrate, or a similar substrate. In some implementations, the substrate 102 may include one or more dielectric layers 118 and/or one or more metal layers 120. Each of the one or more dielectric layers 118 may comprise, for example, an FR4 material, a polyimide material, an epoxy material, an aluminum oxynitride (AlON) material, an aluminum nitride (AlN) material, an aluminum phosphate (AlPO₄) material, an aluminum oxide (Al₂O₃) material, and/or another dielectric material. Each of the one or more metal layers 120 may comprise, for example, tungsten (W), a W alloy, copper (Cu), a Cu alloy, a CuW alloy, molybdenum (Mo), a Mo alloy, a WMo alloy, silver (Ag), and/or an Ag alloy. In some implementations, the substrate 102 may include one or more vias 122. Each of the one or more vias 122 may be hollow (e.g., empty) or filled with, for example, W, a W alloy, Cu, a Cu alloy, a CuW alloy, Mo, a Mo alloy, a WMo alloy, Ag, an Ag alloy, and/or an electrically conductive epoxy (e.g., sintered Ag-epoxy, semi-sintered Ag-epoxy, or Ag-epoxy).

As shown in FIG. 1A, the substrate 102 may include a top surface and a bottom surface. In some implementations, the substrate 102 may include a cavity 124 (e.g., that is formed in the top surface of the substrate 102). For example, a portion of at least one of the one or more dielectric layers 118 and/or a portion of at least one of the one or more metal layers 120 may be removed (e.g., using an etch removal process), or may not be formed, to cause the substrate 102 to include the cavity 124.

The IC driver chip 104 may comprise silicon (Si), indium phosphide (InP), gallium arsenide (GaAs), and/or another similar material. The IC driver chip 104 may be configured to generate and provide an electrical signal to the one or more optical subassemblies 106 (e.g., to respective VCSEL devices 110 of the one or more optical subassemblies 106 to cause the respective VCSEL devices 110 to emit output beams). In some implementations, the IC driver chip 104 may be disposed on a region of the top surface of the substrate 102. For example, as shown in FIG. 1A, the IC driver chip 104 may be disposed on a central region of the top surface of the substrate 102. As further shown in FIG. 1A, the central region may be within the cavity 124 of the substrate 102.

In some implementations, at least one attachment material 126 may be disposed between the substrate 102 and the IC driver chip 104. For example, the at least one attachment material 126 may be disposed between the top surface of the substrate 102 and a bottom surface of the IC driver chip 104. The at least one attachment material 126 may be configured to mechanically and/or electrically attach the IC driver chip 104 to the substrate 102. The at least one attachment material 126 may include, for example, a thermally conductive epoxy (e.g., sintered Ag-epoxy, semi-sintered Ag-epoxy, or Ag-epoxy), a solder, or another material.

In some implementations, the EMI shield 108 may comprise a metal, such as copper (Cu) and/or Cu alloys, nickel (Ni), gold (Au), Aluminum (Al) and/or Al alloys, and/or Zinc (Zn) and/or Zn alloys, among other electrically-conductive materials. The EMI shield 108 may be configured to minimize or prevent an amount of electromagnetic radiation that transmits to other components of the optical assembly 100. The EMI shield 108 may be configured to minimize or prevent an amount of electromagnetic radiation that transmits to or from other components external to the optical assembly 100. In some implementations, the EMI shield 108 may be disposed on a region of the top surface of the substrate 102. For example, as shown in FIG. 1A, the EMI shield 108 may be disposed on a perimeter region of the top surface of the substrate 102 (e.g., not within the cavity 124 of the substrate 102).

In some implementations, the substrate 102 may include one or more metallized sidewalls 128 (e.g., that are formed using a metallization process, a castellation process, and/or a similar process). The one or more metallized sidewalls 128 may be configured to minimize or prevent an amount of electromagnetic radiation that transmits to other components of the optical assembly 100. The one or more metallized sidewalls 128 may be configured to minimize or prevent an amount of electromagnetic radiation that transmits to or from other components external to the optical assembly 100. The one or more metallized sidewalls 128 may be formed on portions of one or more surfaces of the substrate 102 (e.g., an entirety of one or more side surfaces and/or portions of the top surface and/or the bottom surface of the substrate 102) and may comprise a metal, such as Cu, Ni, Au, W, WMo, and/or electrically-conductive epoxies, among other examples.

In some implementations, at least one attachment material 130 may be disposed between the substrate 102 and the EMI shield 108. For example, as shown in FIG. 1A, the at least one attachment material 130 may be disposed between a portion of the top surface of the substrate 102 (e.g., that includes a metallized sidewall 128) and a bottom surface of the EMI shield 108. The at least one attachment material 126 may be configured to mechanically and/or electrically attach the EMI shield 108 to the substrate 102. The at least one attachment material 130 may include, for example, an electrically-conductive epoxy (e.g., sintered Ag-epoxy, semi-sintered Ag-epoxy, or Ag-epoxy), a solder, or another material.

In some implementations, as shown in FIGS. 1A-1B, at least one redistribution layer (RDL) structure 132 may be disposed on respective portions of a surface of the IC driver chip 104 (e.g., the top surface of the IC driver chip 104). The at least one RDL structure 132 may include a set of metal layers (e.g., one or more metal layers that are similar to the one or more metal layers 120 described herein), and/or a set of dielectric layers (e.g., one or more dielectric layers that are similar to the one or more dielectric layers 118 described herein). As further shown in FIGS. 1A-1B, a set of wire bonds 134 may connect the at least one RDL structure 132 to at least one of the one or more metal layers 120 of the substrate 102.

As described above, an optical subassembly 106, of the one or more optical subassemblies 106, may include a VCSEL device 110 (e.g., optical subassembly 106-1 may include VCSEL device 110-1 and/or optical subassembly 106-2 may include VCSEL device 110-2). The VCSEL device 110 may include a substructure 136, a plurality of emitters 138, a microlens component 140, a cathode contact 142, and/or an anode contact 144. The plurality of emitters 138 may be disposed within the substructure 136 of the VCSEL device 110. For example, when the VCSEL device 110 is a top emitting VCSEL device, the plurality of emitters 138 may be disposed within a top portion of the substructure 136 (e.g., so that the plurality of emitters emit the output laser beam from a top surface of the substructure 136). The microlens component 140 may include a plurality of microlenses and may be disposed over the plurality of emitters 138. For example, the microlens component 140 may be disposed over the plurality of emitters 138 (e.g., on the top surface of the substructure 136) such that each emitter 138, of the plurality of emitters 138, emits a portion of the output laser beam via a corresponding microlens of the microlens component 140.

The cathode contact 142 may be disposed on the top surface of the substructure 136 of the VCSEL device 110 (e.g., disposed on a particular region of the top surface of the substructure 136 of the VCSEL device 110 on which the microlens component 140 and the anode contact 144 are not disposed). The anode contact 144 may be disposed on the top surface of the substructure 136 of the VCSEL device 110 (e.g., disposed on a particular region of the top surface of the substructure 136 of the VCSEL device 110 on which the microlens component 140 and the cathode contact 142 are not disposed).

In some implementations, a portion of the VCSEL device 110 may be electrically insulated. For example, at least a bottom surface of the VCSEL device 110 (e.g., that includes a bottom surface of the substructure 136 of the VCSEL device 110) may be electrically insulated. Accordingly, as shown in FIGS. 1A-1B, the VCSEL device 110 may be disposed on the IC driver chip 104. For example, the bottom surface of the VCSEL device 110 may be disposed on the top surface of the IC driver chip 104. In a particular example, as shown in FIGS. 1A-1B, the bottom surface of the VCSEL device 110 may be disposed on a region of the top surface of the IC driver chip 104 on which the at least one RDL structure 132 is not disposed.

In some implementations, at least one attachment material 146 may be disposed between the IC driver chip 104 and the VCSEL device 110. For example, the at least one attachment material 146 may be disposed between the top surface of the IC driver chip 104 and the bottom surface of the VCSEL device 110. The at least one attachment material 146 may be configured to mechanically attach the VCSEL device 110 to the IC driver chip 104. The at least one attachment material 146 may include, for example, a thermally conductive epoxy (e.g., an Ag-epoxy), a solder, or another material.

As described above, an optical subassembly 106, of the one or more optical subassemblies 106, may include an optical element 112 (e.g., optical subassembly 106-1 may include optical element 112-1 and/or optical subassembly 106-2 may include optical element 112-2). The optical element 112 may comprise a glass material (e.g., a glass substrate). In some implementations, the optical element 112 may be (e.g., when the optical assembly 100 is included in a ToF device) a diffractive optical element (DOE) (e.g., at least one diffractive feature may be formed in the glass material of the optical element 112) and/or may be (e.g., when the optical assembly 100 is included in an ToF device) a diffuser (e.g., at least one diffusive feature may be formed in the glass material of the optical element 112). In some implementations, the optical element 112 may include two or more conductive traces 148 (shown as conductive traces 148-1 and 148-2 in FIG. 1B). The two or more conductive traces 148 may be disposed on a bottom surface of the optical element 112 (e.g., on two or more respective regions of the bottom surface of the optical element 112). The two or more conductive traces 148 may comprise a metal, such as Cu, Ni, and/or Au, among other examples.

In some implementations, the optical element 112 may be disposed over the VCSEL device 110. For example, as shown in FIGS. 1A-1B, the bottom surface of the optical element 112 may be disposed over the top surface of the VCSEL device 110. Moreover, as further shown in FIGS. 1A-1B, the two or more conductive traces 148 of the optical element 112 may be disposed over the cathode contact 142 and/or the anode contact 144 of the VCSEL device 110. In some implementations, the two or more attachment structures 114 may be disposed between the optical element 112 and the VCSEL device 110. For example, the two or more attachment structures 114 may be disposed between the two or more conductive traces 148 of the optical element 112 and the cathode contact 142 and/or the anode contact 144 of the VCSEL device 110. The two or more attachment structures 114 may be configured to electrically and/or mechanically connect the two or more conductive traces 148 of the optical element 112 to the cathode contact 142 and/or the anode contact 144 of the VCSEL device 110. For example, as shown in FIG. 1B, the conductive trace 148-1 and the attachment structure 114-1 may be associated with the cathode contact 142 such that the attachment structure 114-1 is disposed between the conductive trace 148-1 and the cathode contact 142 (e.g., to form a first electrical path associated with the cathode contact 142). As another example, as further shown in FIG. 1B, the conductive trace 148-2 and the attachment structure 114-2 may be associated with the anode contact 144 such that the attachment structure 114-2 is disposed between the conductive trace 148-2 and the anode contact 144 (e.g., to form a second electrical path associated with the anode contact 144).

The two or more attachment structures 114 may be electrically conductive and may include, for example, electrically conductive epoxy (e.g., Ag-epoxy and/or anisotropic conductive film). In some implementations, each of the two or more attachment structures 114 may include electrically conductive metal and may be, for example, an Au stud, a Cu column, a Cu pillar, a solder, or another non-spherical structure that includes Au, Ag, Cu, and/or another electrically conductive material.

In some implementations, the one or more sealing structures 116 may be disposed on one or more portions of the VCSEL device 110 and/or one or more portions of the optical element 112. For example, as shown in FIGS. 1A-1B, the one or more sealing structures 116 may be disposed on one or more portions of side surfaces of the VCSEL device 110 (e.g., that include portions of the cathode contact 142 and/or the anode contact 144) and may be disposed on one or more portions of the bottom surface of the optical element 112 (e.g., that include portions of the one or more conductive traces 148). Additionally, or alternatively, the one or more sealing structures 116 may be disposed on one or more portions of the two or more attachment structures 114 (e.g., one or more portions of external surfaces of the two or more attachment structures 114). In some implementations, the one or more sealing structures 116 may form a seal (e.g., a hermetic seal) between the optical element 112 and the VCSEL device 110. For example, the one or more sealing structures 116 may be positioned around the one or more portions of the VCSEL device 110, the one or more portions of the optical element 112, and/or the two or more attachment structures 114, to form a seal and thereby an internal space of the optical subassembly 106 that is bounded by the VCSEL device 110, the optical element 112, the two or more attachment structures 114, and/or the one or more sealing structures 116.

In some implementations, two or more additional attachment structures 150 (shown as additional attachment structures 150-1 and 150-2 in FIG. 1B) may be disposed between the one or more optical subassemblies 106 and the IC driver chip 104. For example, the two or more additional attachment structures 150 may be disposed between the two or more conductive traces 148 of the optical element 112 and the at least one RDL structure 132 of the IC driver chip 104. The two or more additional attachment structures 150 may be configured to electrically connect the two or more conductive traces 148 of the optical element 112 to the IC driver chip 104 (e.g., via the at least one RDL structure 132 of the IC driver chip 104). For example, the additional attachment structure 150-1 may be associated with the cathode contact 142 such that the additional attachment structure 150-1 is disposed between the conductive trace 148-1 and a first region of the top surface of the IC driver chip 104 (e.g., to further form the first electrical path, which electrically connects the cathode contact 142 and the top surface of the IC driver chip 104). As another example, the additional attachment structure 150-2 may be associated with the anode contact 144 such that the additional attachment structure 150-2 is disposed between the conductive trace 148-2 and a second region of the top surface of the IC driver chip 104 (e.g., to further form the second electrical path, which electrically connects the anode contact 144 and the top surface of the IC driver chip 104). The two or more additional attachment structures 150 may include, for example, electrically conductive epoxy (e.g., sintered Ag-epoxy, semi-sintered Ag-epoxy, or Ag-epoxy). In some implementations, each of the two or more additional attachment structures 150 may be a stud, a column, a pillar, or another non-spherical structure that includes Au, Ag, Cu, and/or another electrically conductive material.

In some implementations, one or more encapsulants 152 may be disposed on one or more components of the optical assembly 100. For example, as shown in FIG. 1A, the one or more encapsulants 152 may be disposed on one or more portions of the substrate 102, one or more portions of the IC driver chip 104, and/or one or more portions of the one or more optical subassemblies 106. Each of the one or more encapsulants 152 may be configured to provide mechanical support to the optical assembly 100 and/or one or more components of the optical assembly 100, such as the substrate 102, the IC driver chip 104, and/or the one or more optical subassemblies 106. Each of the one or more encapsulants 152 may include an epoxy (e.g., an insulative epoxy), or a similar material.

In some implementations, a window 154 may be disposed over the one or more optical subassemblies 106. For example, the EMI shield 108 may hold the window 154 over the one or more optical subassemblies 106 (e.g., within an open space formed over the one or more optical subassemblies 106 by the EMI shield 108). The window 154 may be configured to allow light emitted by the VCSEL devices 110 of the optical subassemblies 106 to transmit out of the optical assembly 100 (e.g., to a target). The window 154 may comprise a glass, a polymer, or another transparent material (e.g., that is transparent to the light emitted by the VCSEL devices 110 of the optical subassemblies 106). The window 154 may be configured to prevent dust, debris, humidity, or other contaminants from entering an internal portion of the optical assembly 100 (and therefore from damaging or interfering with the VCSEL devices 110, the IC driver chip 104, and/or the optical elements 112 of the optical subassemblies 106).

As indicated above, FIGS. 1A-1B are provided as an example. Other examples may differ from what is described with regard to FIGS. 1A-1B. In practice, the optical assembly 100 may include additional layers and/or elements, fewer layers and/or elements, different layers and/or elements, or differently arranged layers and/or elements than those shown in FIGS. 1A-1B.

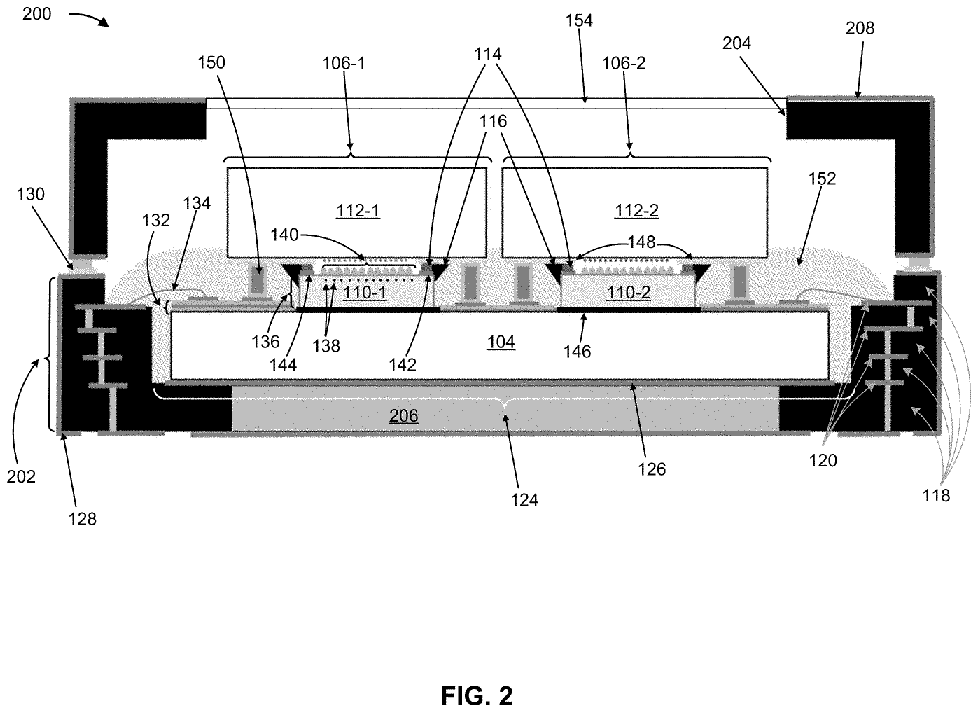

FIG. 2 is a diagram of an example optical assembly 200 for an electro-optical device, such as a ToF device. FIG. 2 illustrates a side cut-away view of the optical assembly 200. As shown in FIG. 2, the optical assembly 200 may be similar to the optical assembly 100 and may include a substrate 202, the integrated circuit (IC) driver chip 104, and the one or more optical subassemblies 106 (shown as optical subassemblies 106-1 and 106-2), and/or a housing 204.

The substrate 202 may be a fire resistant (FR) substrate, such as a FR4 substrate. The substrate 202 may comprise the same or similar elements as the substrate 102, such the one or more dielectric layers 118, the one or more metal layers 120, the cavity 124, and/or the one or more metallized sidewalls 128. In some implementations, the substrate 202 may include a core 206. The core 206 may be thermally conductive and may comprise, for example, W, a W alloy, Cu, a Cu alloy, a Zn alloy, a Al alloy, an Ag alloy, and/or another thermally conductive material.

The housing 204 may be used as an alternative to the EMI shield 108. The housing 204 may comprise a polymer material. In some implementations, the housing 204 may comprise an electrically conductive material (e.g., an electrically conductive polymer material) and may be configured to minimize or prevent an amount of electromagnetic radiation that transmits to other components of the optical assembly 200. The housing 204 may be configured to minimize or prevent an amount of electromagnetic radiation that transmits to or from other components external to the optical assembly 200. Additionally, or alternatively, the housing 204 may comprise a non-electrically conductive material (e.g., a dielectric polymer material) and may include a surface coating 208. The surface coating 208 may include, for example, a metal surface coating (e.g., that comprises Cu, Ni, or Au), a carbon (C) surface coating, or another electrically-conductive surface coating, and may be configured to minimize or prevent an amount of electromagnetic radiation that transmits to other components of the optical assembly 200 and/or to minimize or prevent an amount of electromagnetic radiation that transmits to or from other components external to the optical assembly 200.

In some implementations, the housing 204 may be disposed on a region of a top surface of the substrate 202 (e.g., in a similar manner as that of the EMI shield 108 disposed on the substrate 102, as described herein in relation to FIG. 1A). For example, as shown in FIG. 2, the housing 204 may be disposed on a perimeter region of the top surface of the substrate 202 (e.g., not within the cavity 124 of the substrate 202).

As indicated above, FIG. 2 is provided as an example. Other examples may differ from what is described with regard to FIG. 2. In practice, the optical assembly 200 may include additional layers and/or elements, fewer layers and/or elements, different layers and/or elements, or differently arranged layers and/or elements than those shown in FIG. 2.

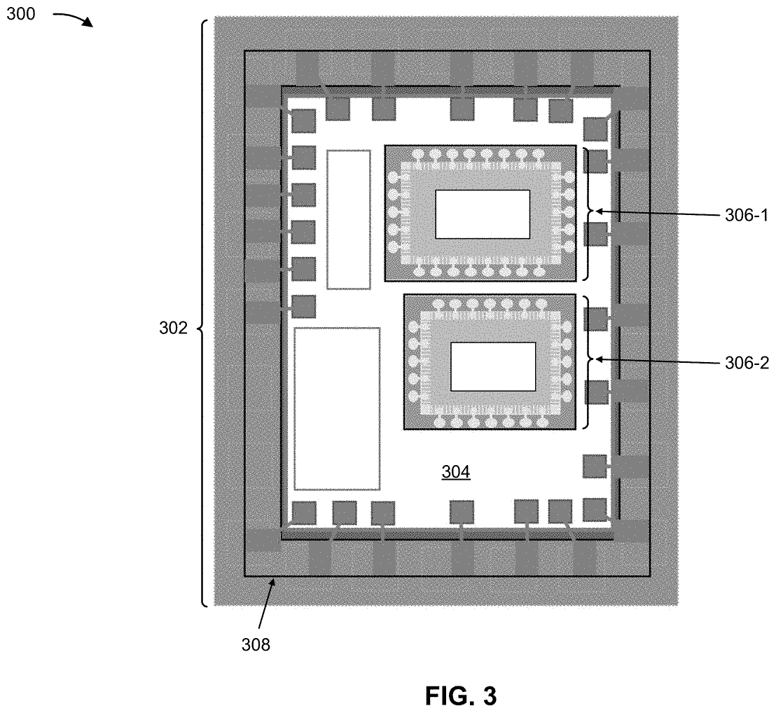

FIG. 3 illustrates a top-down view of an example optical assembly 300. The optical assembly 300 may be the same as, or similar to, the optical assembly 100 described herein in relation to FIGS. 1A-1B and/or the optical assembly 200 described herein in relation to FIG. 2. The optical assembly may include a substrate 302, an IC driver chip 304, one or more optical subassemblies 306 (shown as optical subassemblies 306-1 and 306-2), and/or an EMI shield or housing 308 (e.g., that are the same as or similar to corresponding elements described herein in relation to FIGS. 1A, 1B, and 2).

As shown in FIG. 3, the IC driver chip 304 may be disposed on a top surface of the substrate 302 (e.g., on a central region of the top surface of the substrate 302). As further shown in FIG. 3, the one or more optical subassemblies 306 may be disposed on a top surface of the IC driver chip 304. As additionally shown in FIG. 3, the EMI shield or housing 308 may disposed on the top surface of the substrate 302 (e.g., on a perimeter region of the top surface of the substrate 302).

As indicated above, FIG. 3 is provided as an example. Other examples may differ from what is described with regard to FIG. 3. In practice, the optical assembly 300 may include additional layers and/or elements, fewer layers and/or elements, different layers and/or elements, or differently arranged layers and/or elements than those shown in FIG. 3.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “bottom,” “above,” “upper,” “top,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical subassembly, comprising:
a vertical cavity surface emitting laser (VCSEL) device;
an optical element disposed above a top surface of the VCSEL device; and
two or more attachment structures disposed between the VCSEL device and the optical element, wherein:
the VCSEL device includes:
a cathode contact disposed on the top surface of the VCSEL device, and
an anode contact disposed on the top surface of the VCSEL device;
the optical element includes two or more conductive traces on a bottom surface of the optical element; and
the two or more attachment structures are disposed between the two or more conductive traces of the optical element, and the cathode contact and the anode contact of the VCSEL device.

2. The optical subassembly of claim 1, wherein the optical element comprises a glass material and is at least one of a diffractive optical element or a diffuser.

3. The optical subassembly of claim 1, wherein each conductive trace of the two or more conductive traces is configured to at least one of:
transmit an electrical signal to or from the VCSEL device; or
prevent transmission of the electrical signal to or from the VCSEL device when at least one of the optical element or the conductive trace are damaged or broken.

4. The optical subassembly of claim 1, wherein each of the two or more conductive traces includes at least one of copper, nickel, or gold.

5. The optical subassembly of claim 1, wherein a particular attachment structure, of the two or more attachment structures, is configured to electrically connect a particular conductive trace, of the two or more conductive traces of the optical element, to the cathode contact or the anode contact of the VCSEL device.

6. The optical subassembly of claim 1, wherein each of the two or more attachment structures includes at least one of gold or copper.

7. The optical subassembly of claim 1, wherein each of the two or more attachment structures is an Au stud, a Cu column, or a Cu pillar.

8. The optical subassembly of claim 1, wherein the VCSEL device includes a microlens component that is disposed on the top surface of the VCSEL device.

9. The optical subassembly of claim 1, further comprising:
one or more sealing structures that form a seal between the optical element and the VCSEL device.

10. An optical assembly, comprising:
an integrated circuit (IC) driver chip;
an optical subassembly disposed on the IC driver chip that includes:
a vertical cavity surface emitting laser (VCSEL) device,
an optical element disposed above a top surface of the VCSEL device, and
two or more attachment structures disposed between the VCSEL device and the optical element; and
two or more additional attachment structures disposed between the IC driver chip and the optical subassembly, wherein:
the VCSEL device includes:
a cathode contact disposed on the top surface of the VCSEL device, and
an anode contact disposed on the top surface of the VCSEL device;
the optical element includes two or more conductive traces on a bottom surface of the optical element; and
the two or more attachment structures are disposed between the two or more conductive traces of the optical element, and the cathode contact and the anode contact of the VCSEL device.

11. The optical assembly of claim 10, the two or more additional attachment structures are disposed between the two or more conductive traces of the optical element and a top surface of the IC driver chip.

12. The optical assembly of claim 10, wherein the two or more additional attachment structures are configured to electrically connect the two or more conductive traces of the optical element to the IC driver chip.

13. The optical assembly of claim 10, wherein each of the two or more additional attachment structures includes at least one of gold or copper.

14. The optical assembly of claim 10, wherein each of the two or more additional attachment structures is a stud, a column, or a pillar.

15. The optical assembly of claim 10, wherein the IC driver chip is configured to provide an electrical signal to the VCSEL device, wherein:
the electrical signal is to be transmitted from the IC driver chip to the VCSEL device via a particular additional attachment structure, of the two or more additional attachment structures, a particular conductive trace, of the two or more conductive traces of the optical element, and a particular attachment structure of the two or more attachment structures.

16. An optical assembly, comprising:
a substrate;
an integrated circuit (IC) driver chip disposed on the substrate;
an optical subassembly disposed on the IC driver chip that includes:
a vertical cavity surface emitting laser (VCSEL) device,
an optical element disposed above a top surface of the VCSEL device, and
two or more attachment structures disposed between the VCSEL device and the optical element; and
two or more additional attachment structures disposed between the IC driver chip and the optical subassembly, wherein:
the VCSEL device includes:
a cathode contact disposed on the top surface of the VCSEL device, and
an anode contact disposed on the top surface of the VCSEL device;
the optical element includes two or more conductive traces on a bottom surface of the optical element; and
the two or more attachment structures are disposed between the two or more conductive traces of the optical element, and the cathode contact and the anode contact of the VCSEL device.

17. The optical assembly of claim 16, wherein each of the two or more attachment structures and the two or more additional attachment structures is a non-spherical structure.

18. The optical assembly of claim 16, further comprising an electromagnetic interference shield comprising at least one of copper, nickel, gold, aluminum, or zinc.

19. The optical assembly of claim 16, further comprising an electromagnetic interference (EMI) shield, wherein:
the EMI shield is disposed on a perimeter region of a top surface of the substrate; and
the IC driver chip is disposed on a central region of the top surface of the substrate.

20. The optical assembly of claim 16, further comprising a housing, wherein:
the housing includes at least one of an electrically conductive polymer material; or
the housing includes at least one of a dielectric polymer material,
wherein the housing includes a metal surface coating or a carbon surface coating.
